(19) United States
(12) Patent Application Publication
(10) Pub. No.: US 2003/0116184 A1
(43) Pub. Date: Jun. 26, 2003

(54) Focused solar energy collector

(76) Inventor: Kimberley Derby-Lewis, Wilderness (ZA)

Correspondence Address: KEUSEY, TUTUNJIAN & BITETTO, P.C., 14 VANDERVENTER AVENUE, SUITE 128, PORT WASHINGTON, NY, 11050, US

(21) Appl. No.: 10/239,361

(22) PCT Filed: Mar. 22, 2001
(86) PCT No.: PCT/ZA01/00032

(30) Foreign Application Priority Data
Mar. 23, 2000 (ZA) 2000/1443
Dec. 4, 2000 (ZA) 2000/7132

(51) Int. Cl. H01L 31/00

(52) U.S. Cl. 136/246; 136/259; 359/742

(57) ABSTRACT

The solar energy collector comprises a solar energy converter, a base member which carries the solar energy converter and a domed fresnel lens including a transparent hemispherical shell mounted on the base member over the solar energy converter with a diametrical line across the base of the shell being in register with a long axis of the solar energy converter, and fresnel lens prism elements on the inner surface of the shell which are each parallel to a plane which passes through the pole of the shell and the long axis of the solar energy converter and which focus parallel ray solar radiation which passes through the shell on either side of the plane into a line focus on the solar energy converter irrespective of the position of the sun relatively to the lens shell while the sun is situated in the plane.

### FIELD OF THE INVENTION

This invention relates to a solar energy collector and to a domed fresnel lens for use with such a collector.

### BACKGROUND TO THE INVENTION

Domed fresnel lenses are known. The construction and required parameters of such a lens are described in a paper by F Erismann and published in the April 1997 edition of Optical Engineering and Manufacturing entitled “Design of Plastic Aspheric Fresnel Lens with a Spherical Shape”. The lens referred to in Erismann's paper is in the form of a spherical shell which is made from a high density polyethylene and includes circular lens prisms which are concentric about the central axis of the shell and extend from the base of the inner surface of the shell over the inner surface in a parallel relationship to each other up to the central upper point or pole of the dome. With domed lenses of this type parallel light rays from an external source which strike the outer surface of the shell, are refracted through the shell material and focused by the circular prisms on the inner surface of the shell to a point focus at the base of the shell. For maximum light, and so energy concentration, of the light rays at the focal point of the lens the upper central portion of the dome needs always to be directed at the light source.

Where domed spherical lenses of the above type are used in solar energy collectors for photovoltaic or thermo electric generation of electric current or for heat generation, the sun moving over the domed lens of such a static energy collector will cause the orientation and direction of the incoming light energy to the collector to be constantly changing. The lens will therefore have a low light and energy concentration at the fixed position of the photovoltaic cells in the dome except during the time when the sun is aligned or nearly so with the axis passing through the centre of the lens dome onto the base position of the solar cells of the collector. Additionally, the seasonal shift of the sun's apparent orbital path will further aggravate the diminished efficiency of the lens and in all probability render the lens useless when the sun is towards its extreme seasonal positions. In overcoming these problems with domed point focus and cylindrical or partially cylindrical line focus fresnel energy collecting lenses, such as those described in the specifications of U.S. Pat. Nos. 4,711,972; 4,058,110; 4,011,857 and 4,069,812, all require complicated electrically motorised sun tracking drive arrangements. The drive arrangements are not only required to roll the lenses and the energy collectors they serve to enable the lenses to be optimally sun tracking on a daily basis but are also required to transversely tilt the lenses to be seasonally sun tracking. The expense of these driven solar energy collectors, which are often computer guided, place them well beyond the financial reach of poor rural people who are the very people who need inexpensive energy.

### SUMMARY OF THE INVENTION

A solar energy collector according to the invention comprises: an elongated solar energy converter, a base member on which the solar energy converter is mounted, and a domed fresnel lens with said lens including a hemispherical shell which is made from a transparent material, and is mounted on the base member over the solar energy converter with a diametrical line across the circular base of the shell being in register with the long axis of the solar energy converter, and fresnel lens prism elements on the inner surface of the shell which are each parallel to a plane which passes through the pole of the shell and the long axis of the solar energy converter and which are adapted to focus parallel ray solar radiation which passes through the shell on either side of the plane into a line focus on the solar energy converter irrespective of the position of the sun relatively to the lens shell while the sun is situated in the plane.

Conveniently the inner surface of the shell includes grooves which between them define the fresnel lens prism elements. The outer surface of the dome may be uniformly smooth.

The elongated energy converter is preferably a linear arrangement of solar cells which are adapted to convert solar radiation into electrical energy. The solar cells may be photovoltaic cells which are arranged in an unbroken linear arrangement and which are connected in parallel to each other and to electrical connectors on the base member.

The solar cell arrangement may include a heat sink on the underside of each of the solar cells. In a preferred form of the invention the heat sink is a continuous heat pipe onto a surface of which the underside of the solar cells are mounted and which extends through the base member for a portion of it to be on the outside of the dome enclosed surface of the base member. The heat pipe may be in the form of a closed loop heat pipe with a portion of the loop carrying the solar cells in the domed enclosure above the base member and the remainder of the loop situated beneath the base member for heat dissipation.

The underside of the base member forms a surface of a water tank in which the heat dissipation portion of the heat pipe is located with the water tank including water inlet and outlet connections. The solar energy collector conveniently includes a second closed loop heat pipe with a portion of the loop being located in the water tank and the remainder of the loop exposed to atmosphere on the outside of the tank to control the temperature of the tank water to at or below that of the vaporisation temperature of the bi-phase fluid in the first heat pipe.

A domed fresnel lens for focusing radiant solar energy in a solar energy collector according to the invention comprises: a hemispherical shell which is made from a transparent material, and carries on its domed inner surface fresnel lens prism elements which are each parallel to a plane which passes through the pole of the shell and diametric line intersection points on the circular base edge of the shell and which are adapted to focus parallel ray solar radiation which passes through the shell on either side of the plane into a line focus on a line joining the diametrical points on the base edge of the shell irrespective of the position of the sun relatively to the lens shell while the sun is in the plane.

The fresnel lens may include grooves in the inner surface of the shell which between them define the fresnel lens prism elements. The outer surface of the dome may be uniformly smooth.

### BRIEF DESCRIPTION OF THE DRAWINGS

The invention is now described by way of example only with reference to the drawings in which:

FIG. 1 is a sectioned side elevation of the domed fresnel lens of the invention,

FIG. 2 is an under plan of the FIG. 1 lens,

FIG. 3 is a diagrammatic perspective view of a solar energy collector incorporating the lens of FIGS. 1 and 2,

FIG. 4 is a sectioned side elevation of a solar energy collector including the lens of FIGS. 1 and 2, and

FIG. 5 is a plan view of the base of the FIG. 4 collector with the lens removed.

### DETAILED DESCRIPTION OF THE ILLUSTRATED EMBODIMENTS

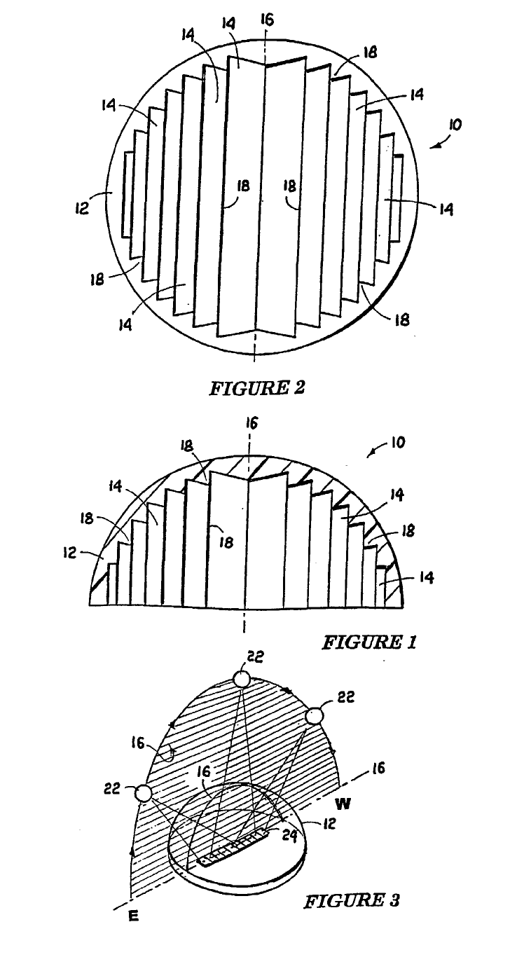

The domed wide angle fresnel lens 10 of the invention is shown in FIGS. 1 and 2 of the drawings to comprise a hemispherical shell 12 which has a smooth outer surface and includes grooves 14 which are parallel to an imaginary plane which is represented in FIGS. 1 to 4 of the drawings by the chain line 16. The plane passes through the pole of the hemisphere at the upper end of the dome as shown in FIG. 1 and the diametrical position of the plane line 16 across the open base of the dome as shown in FIG. 2.

The shell 12 is made from a suitable transparent plastics material which is resistant to sun and general outdoor degradation. A suitable plastics material has been found to be PERSPEX which is injection moulded or preferably hot pressed into the shape shown in FIGS. 1 and 2.

The grooves 14 on either side of the plane 16 are oppositely shaped as shown in FIGS. 1 and 2, to provide between them fresnel lens prism elements 18. The cross-sectional shape of the shell grooves 14 and so the prisms 18 which they define may vary from the saw tooth shape illustrated in the drawings. The shape of the prisms of the lens of the invention are designed according to the same design procedures as are the conventional domed fresnel lenses having horizontally concentric point focus grooves and prisms. The fresnel lens groove and prism design criteria are explained in the Erismann paper referred to in the preamble to this specification.

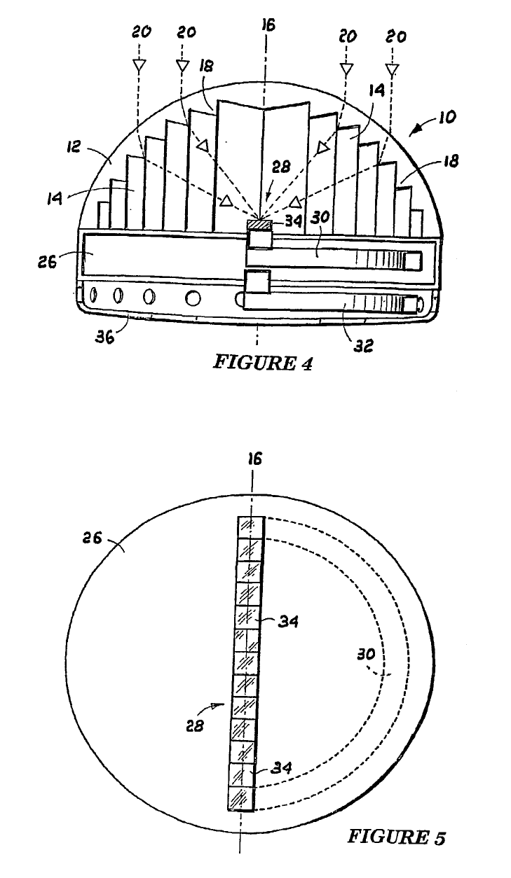

The vertically parallel groove 14 and prism 18 arrangement in the lens of this invention is designed to focus parallel rays of sunlight 20 and so solar energy which impinges on and pass through the shell 12, from the prisms 18 on the inner wall of the shell, on both sides of the plane 16, inwardly and downwardly, as shown in FIG. 4, onto a common line focus which extends along the base of the domed lens in register with the plane 16.

The above positioning of the line focus of the lens of the invention is achieved by making the outer radius of the outer surface of the domed shell 12 equal to the focal length of the lens. The current dome lens of the invention has a radius of 300 mm. Although not essentially so, current experiments with the lens indicate that 60 prism defining grooves on each side of the plane 16 provides satisfactorily focused solar power.

The principal advantage of the domed lens of the invention over known dome lenses is that all incoming solar radiation from the outer surface of the shell 12, including that from the outer regions of the shell, is concentrated onto the lens line focus while the lens is statically mounted with its plane 16 including the daily path of motion of the sun 22, as diagrammatically illustrated in FIG. 3. Although the radiation lines onto a target 24 at the base of the shell and centred on the plane 16 are shown diverging in the plane 16 only, the radiation lines are of course parallel and strike the entire surface of the lens dome to cause the radiation lines to be focused inwardly from the opposite sides of the plane 16 onto the line focus as illustrated in FIG. 4.

The diverging sun radiation lines in FIG. 4 serve only to illustrate that while the domed lens of the invention is and remains daily static, in the solar plane 16, the wide angle focus of the lens enables optimum radiant energy from the sun to be line focused accurately onto the target 24 irrespective of the position of the sun even at mid-morning and afternoon when the side of the shell opposite the radiation incident side is partially shadowed. Obviously the focused energy on the target 24 is greatest at and on either side of mid-day when the maximum area of the dome is fully exposed to the sun radiation. The relatively small loss of focused energy at lower sun elevations, when the domed lens of the invention is used on a solar energy collector, is a small trade-off against the high cost of the electrically motorised sun tracking mechanisms which are required by known fresnel lenses on solar energy collectors.

The lens of the invention, when used on a solar energy collector, is capable of remaining static, as described above, without any interference for a number of days without any discernible loss of focused energy performance. As the path of the sun shifts seasonally from over the pole of the shell 12 it is necessary to periodically tilt the shell transversely to its originally aligned positioned in the plane 16 to bring the path of the sun back into a coplanar relationship with the lens. This realignment of the lens with the moved sun path is, however, easily achieved manually without the need of a computer driven motorised tracking device as will be explained below.

In its most basic form a solar energy collector of the invention could comprise a suitable base to which the domed shell 12 of the invention is attached and a target, such as the target 24 in FIG. 3, which is positioned on the base as described above and consists of a linear arrangement of solar cells which are mounted on a suitable heat sink and which are suitably connected together electrically and to electrical power take-off terminals on the collector. The currently preferred embodiment of the collector of the invention is, however, illustrated in FIGS. 4 and 5.

The embodiment of the solar energy collector of the invention which is illustrated in FIGS. 4 and 5 is shown in the drawings to include a water tank 26, a solar energy target 28, a first heat pipe 30, a second heat pipe 32 and the domed fresnel lens 10 of the invention.

The water tank 26 is a closed tank and includes a water inlet and a valve controlled outlet, neither of which are shown in the drawings.

The first heat pipe 30 is of a closed loop D-shaped design, as will perhaps be more appreciated from FIG. 5. The vertical leg of the D is raised above the dotted curved portion, shown in FIG. 5, which is situated in the tank 26 with the leg portion of the pipe passing through the upper surface of the tank which provides a closed base for the lens 10.

The solar energy target 28 is a solar energy converter, which in this embodiment of the invention, consists of photovoltaic cells 34 which are, as shown in FIG. 5, arranged in an unbroken linear arrangement and are attached to the upper surface of the vertical leg of the heat pipe 30. The portion of the heat pipe 30 above the upper surface of the tank 26 and so the cells 34 lie on the planar line 16 across the dome base as shown in FIG. 4. The cells 34 are, in this embodiment of the invention, electrically connected to each other in parallel and to electrical terminals which are not shown in the drawing but are suitably placed on the collector.

The second heat pipe 32 is identical to the first with its curved portion located beneath the base of the tank 26 in an air ventilated protective casing 36. The vertical leg of the D is located in the water tank 26, as shown in FIG. 4.

In use, the solar energy collector of FIGS. 4 and 5 is mounted on a simple to operate, non-electrical, device by means of which it may be manually tilted about an axis which lies in the plane 16 to realign when necessary the dome lens plane 16 with a plane containing the sun's apparent path. Such a device may consist of a simple tripod with one of its legs, on a side of perhaps the casing 36, in a position normal to the plane 16, being simply adjustable in length against an adjustment scale of some sort to cater for the seasonal variation of the sun's path.

The operation of the domed lens is described above and requires no daily positional adjustment. The focused solar energy impinging on the cells 34 heats the cells 34 with the heat on the underside of the cells being absorbed and dissipated into water in the tank 26 by the conventional vaporisation of the bi-phase fluid in the heat pipe 30. The dissipated heat heats the water in the tank 26 while the electricity generated by the cells is battery stored or used directly.

The purpose of the heat pipe 32 is to control by heat dissipation to atmosphere, the temperature of the water in the tank 26 to at or below that of the vaporisation temperature and so pressure of the bi-phase fluid in the first heat pipe.

1. A solar energy collector comprising:
an elongated solar energy converter,
a base member on which the solar energy converter is mounted, and
a domed fresnel lens with said lens including
a hemispherical shell
which is made from a transparent material, and
is mounted on the base member over the solar energy converter
with a diametrical line across the circular base of the shell being in register with the long axis of the solar energy converter, and
fresnel lens prism elements on the inner surface of the shell which
are each parallel to a plane which passes through the pole of the shell and the long axis of the solar energy converter and
which are adapted to focus parallel ray solar radiation which passes through the shell on either side of the plane into a line focus on the solar energy converter irrespective of the position of the sun relatively to the lens shell while the sun is situated in the plane.

2. A solar energy collector as claimed in claim 1 including grooves in the inner surface of the shell which between them define the fresnel lens prism elements.

3. A solar energy collector as claimed in either one of claims 1 or 2 wherein the outer surface of the dome is uniformly smooth.

4. A solar energy collector as claimed in any one of the above claims wherein the elongated energy converter is a linear arrangement of solar cells which are adapted to convert solar radiation into electrical energy.

5. A solar energy collector as claimed in claim 4 wherein the solar cells are photovoltaic cells which are arranged in an unbroken linear arrangement and which are connected in parallel to each other and to electrical connectors on the base member.

6. A solar energy collector as claimed in either one of claims 4 or 5 wherein the solar cell arrangement includes a heat sink on the underside of each of the solar cells.

7. A solar energy collector as claimed in claim 6 wherein the heat sink is a heat pipe onto a surface of which the underside of the solar cells are mounted and which extends through the base member for a portion of it to be on the outside of the dome enclosed surface of the base member.

8. A solar energy collector as claimed in claim 7 wherein the heat pipe is a closed loop heat pipe with a portion of the loop carrying the solar cells in the domed enclosure above the base member and the remainder of the loop situated beneath the base member for heat dissipation.

9. A solar energy collector as claimed in claim 7 wherein the underside of the base member forms a surface of a water tank in which the heat dissipation portion of the heat pipe is located with the water tank including water inlet and outlet connections.

10. A solar energy collector as claimed in claim 9 including a second closed loop heat pipe with a portion of the loop being located in the water tank and the remainder of the loop exposed to atmosphere on the outside of the tank to control the temperature of the tank water to at or below that of the vaporisation temperature of the bi-phase fluid in the first heat pipe.

11. A domed fresnel lens for focusing radiant solar energy in a solar energy collector comprising:
a hemispherical shell which
is made from a transparent material, and
carries on its domed inner surface fresnel lens prism elements
which are each parallel to a plane which passes through the pole of the shell and diametric line intersection points on the circular base edge of the shell and which
are adapted to focus parallel ray solar radiation which passes through the shell on either side of the plane into a line focus on a line joining the diametrical points on the base edge of the shell irrespective of the position of the sun relatively to the lens shell while the sun is in the plane.

12. A domed fresnel lens as claimed in claim 11 including grooves in the inner surface of the shell which between them define the fresnel lens prism elements.

13. A domed fresnel lens as claimed in either one of claims 11 or 12 wherein the outer surface of the dome is uniformly smooth.

14. A domed fresnel lens as claimed in any one of claims 11 to 13 wherein the domed lens is made from a suitable plastics material.

15. A domed fresnel lens as claimed in claim 14 wherein the plastics material is PERSPEX.
